(19) United States
(12) Patent Application Publication
(10) Pub. No.: US 2014/0014896 A1
(43) Pub. Date: Jan. 16, 2014

(54) LIGHT EMITTING DIODE DEVICE USING CHARGE ACCUMULATION AND METHOD OF MANUFACTURING THE SAME

(71) Applicant: SAMSUNG ELECTRONICS CO., LTD., Suwon-si (KR)

(72) Inventors: Dae-young CHUNG, Yongin-si (KR); Kyung-sang CHO, Gwacheon-si (KR)

(73) Assignee: SAMSUNG ELECTRONICS CO., LTD., Suwon-si (KR)

(21) Appl. No.: 13/791,213

(22) Filed: Mar. 8, 2013

(30) Foreign Application Priority Data
Jul. 16, 2012 (KR) 10-2012-0077367

(51) Int. Cl. H01L 33/14; H01L 33/04

(52) U.S. Cl. CPC H01L 33/14; H01L 33/04
USPC 257/13; 438/47

(57) ABSTRACT

A light emitting device using charge accumulation and a method of manufacturing the light emitting device are provided. The light emitting device includes a substrate, a first electrode formed on the substrate, a hole transport layer formed on the first electrode, an electron transport layer formed on the hole transport layer, and a second electrode formed on the electron transport layer. A thickness of the hole transport layer may be greater than 20 nm and a thickness of the electron transport layer may be greater than 40 nm. A quantum dot (QD) layer may be disposed between the hole transport layer and the electron transport layer.

### CROSS-REFERENCE TO RELATED APPLICATIONS

This application claims priority from Korean Patent Application No. 10-2012-0077367, filed on Jul. 16, 2012, in the Korean Intellectual Property Office, the disclosure of which is incorporated herein in its entirety by reference.

### BACKGROUND

1. Field

Devices and methods consistent with the present disclosure relate to a light emitting diode device and a method of manufacturing the same, and more particularly, to a light emitting diode device using charge accumulation and a method of manufacturing the device.

2. Description of the Related Art

A light emitting diode (LED) may be used as a light source in a flat TV or a flat display. Also, an LED may be used as a illumination means. Various types of LEDs, such as organic light emitting diodes (OLEDs), quantum dot LEDs (QD-LEDs), and the like have been studied with the goal of increasing a degree of color realization while reducing driving voltage of the LEDs.

A quantum dot LED (QD-LED) is a light emitting diode device that may realize a low-voltage operation and a high color purity using a quantum dot (QD) layer as an emission layer. In this regard, a QD-LED is believed to be the display and lighting fixture of the next generation.

### SUMMARY

Provided is a light emitting diode (LED) that may relatively reduce driving voltage relatively according to an increase of a thickness of one or more transport layers in the LED.

Provided is a method of manufacturing the LED.

Additional aspects will be set forth in part in the description which follows and, in part, will be apparent from the description, or may be learned by practice of the presented embodiments.

According to an aspect of an exemplary embodiment, a light emitting diode may be an organic light emitting diode (OLED) or a quantum dot-LED (QD-LED), including at least a hole transport layer and an electron transport layer. The hole transport layer and the electron transport layer may be sequentially stacked. In such light emitting diode, a thickness of at least one of the hole transport layer and the electron transport layer may be thicker than a conventional thickness of at least one of the hole transport layer and the electron transport layer.

A QD layer may be interposed between the first charge transport layer and the second charge transport layer.

The hole transport layer, the electron transport layer, and the QD layer may form a micro optical cavity.

The hole transport layer and the electron transport layer may each be a QD layer, a monomolecular layer, or a high molecular layer (a polymer layer).

According to an aspect of another exemplary embodiment, a method of manufacturing a light emitting device may include forming a first electrode formed on a substrate, forming a hole transport layer on the first electrode, forming an electron transport layer on the hole charge transport layer, and forming a second electrode on the electron transport layer, wherein at least one of the hole transport layer and the electron transport layer has is formed with a thickness that is greater than a conventional thickness thereof.

In the method, a QD layer may be interposed between the hole transport layer and the electron transport layer.

The hole transport layer, the electron transport layer, and the QD layer may form a micro optical cavity.

According to an aspect of another exemplary embodiment, a light emitting diode may be an OLED or a QD-LED, including an emission layer formed on at least one of a hole transport layer and an electron transport layer, wherein a thickness of at least one of the hole transport layer and the electron transport layer may be thicker than a convention thickness thereof. Accordingly, a number of electrons/holes not participating in an illuminating process may be reduced, and thus a luminescent efficiency may be increased. Also, in the case of the QD-LED, as a thickness of one of the hole transport layer and the electron transport layer increases, an increased number of holes or electrons may be accumulated at each of a first interface between the QD layer and the electron transport layer or a second interface between the QD layer and the hole transport layer. That is, an increased number of electrons may be accumulated at the first interface, or an increased number of holes may be accumulated at the second interface. Due to such electrons/holes accumulation, an increased number of holes or electrons may participate in the illuminating process, thus a quantum efficiency of the QD-LED increases and a luminescent efficiency may also be increased. Moreover, although thicknesses of the electron transport layer and the hole transport layer increase, a degree of an increase in actual driving voltage may be lower than an expected value due to a voltage difference in the QD-LED caused by the electrons/holes accumulation. Therefore, a relative driving voltage of the light emitting diode may be reduced compared to the increase in thicknesses of the electron transport layer and the hole transport layer.

In addition, as a thickness of one layer of the electron transport layer or the hole transport layer increases compared to the conventional thickness of the layer, the QD layer and the hole transport layer may form a micro optical cavity. Thus, an intensity of the light of the particular wavelengths may be increased.

### BRIEF DESCRIPTION OF THE DRAWINGS

These and/or other exemplary aspects and advantages will become apparent and more readily appreciated from the following description of exemplary embodiments, taken in conjunction with the accompanying drawings in which:

FIG. 1 is a graph showing an absorption spectrum of an electron transport layer (F8BT) and a photoluminescence spectrum;

FIG. 2 is a graph showing an absorption spectrum of a hole transport layer (TFB) and a photoluminescence spectrum;

FIG. 3 is a graph showing an absorption spectrum of a CdSe quantum dot (QD) layer;

FIG. 4 is a schematic view illustrating a process of photoluminescence (PL) of the electron transport layer and the hole transport layer being delivered to the QD layer;

FIG. 5 is a cross-sectional view illustrating charge accumulation according to energy level difference between the electron transport layer and the hole transport layer in a QD light emitting diode (QD-LED) device according to an exemplary embodiment;

FIG. 6 is a view illustrating a potential difference inside the QD-LED device according to the charge accumulation of FIG. 5;

FIG. 7 is a cross-sectional view of the QD-LED according to an exemplary embodiment;

FIG. 8 is a cross-sectional view of an organic light emitting diode (OLED) according to another exemplary embodiment;

FIG. 9 is a table showing an increase in a luminescence efficiency and a relative decrease in a driving voltage according to an increase in thicknesses of the electron transport layer and the hole transport layer in the light emitting device of any one of FIGS. 7 and 8;

FIG. 10 is a graph showing current density change when only a thickness of the hole transport layer is changed in the QD-LED according to an exemplary embodiment;

FIG. 11 is a graph showing luminance change when only a thickness of the hole transport layer is changed in the QD-LED according to an exemplary embodiment;

FIG. 12 illustrates an electroluminescence (EL) spectrum when only a thickness of the hole transport layer is changed in the QD-LED according to an exemplary embodiment;

FIG. 13 illustrates an electroluminescence (EL) spectrum as a micro optical cavity is formed when only a thickness of the electron transport layer is changed in the QD-LED according to an exemplary embodiment;

FIG. 14 illustrates an electroluminescence (EL) spectrum as a micro optical cavity is formed when only a thickness of the hole transport layer is changed in the QD-LED according to an exemplary embodiment.

### DETAILED DESCRIPTION

Reference will now be made in detail to exemplary embodiments which are illustrated in the accompanying drawings, wherein like reference numerals refer to the like elements throughout. In this regard, the exemplary embodiments may have different forms and should not be construed as being limited to the descriptions set forth herein. Accordingly, the exemplary embodiments are merely described below, by referring to the figures, to explain aspects of the present description. As used herein, the term “and/or” includes any and all combinations of one or more of the associated listed items.

Hereinafter, a light emitting diode (LED) device using charge accumulation and a method of manufacturing the device according to an exemplary embodiment will be described in detail. In the process, thicknesses of layers or areas illustrated in the drawings are exaggerated for clarity of the present application.

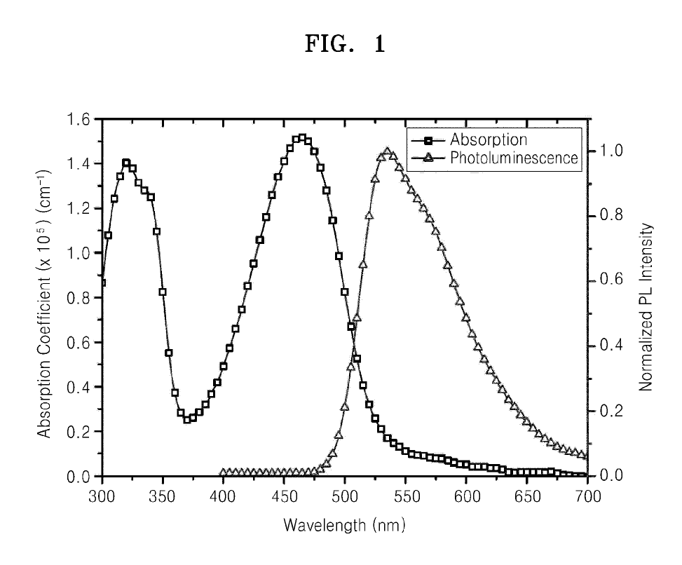

FIG. 1 illustrates absorptivity and photoluminescence spectra with respect to an electron transport layer of a quantum dot-LED (QD-LED) device, which is an example of a LED device according to an exemplary embodiment.

In FIG. 1, a graph shown with a reference figure □ represents an absorption spectrum, and a graph shown with a reference figure Δ represents a photoluminescence spectrum. A material of the electron transport layer that has such properties may be, for example, F8BT.

Referring to FIG. 1, a luminescent center of the electron transport layer is green.

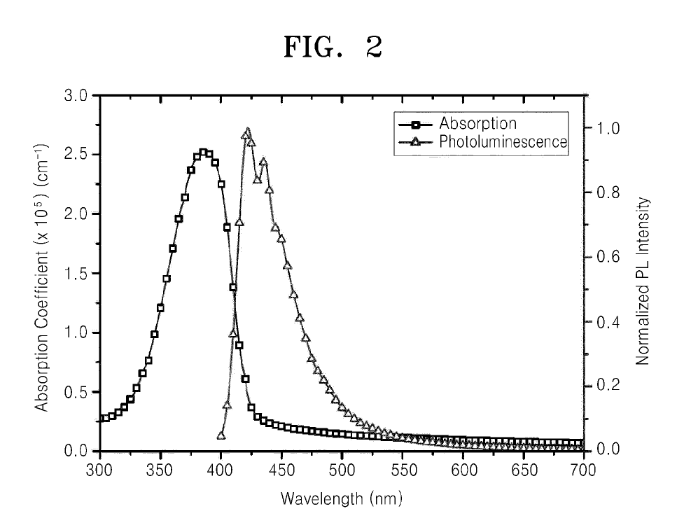

FIG. 2 illustrates absorptivity and photoluminescence spectra with respect to a hole transport of a QD-LED device, which is an example of an LED device according to an exemplary embodiment.

In FIG. 2, a graph shown with a reference figure □ represents an absorption spectrum, and a graph shown with a reference figure Δ represents a photoluminescence spectrum. A material of the hole transport layer that has such properties may be, for example, F8BT.

Referring to FIG. 2, a luminescent center of the hole transport layer is blue.

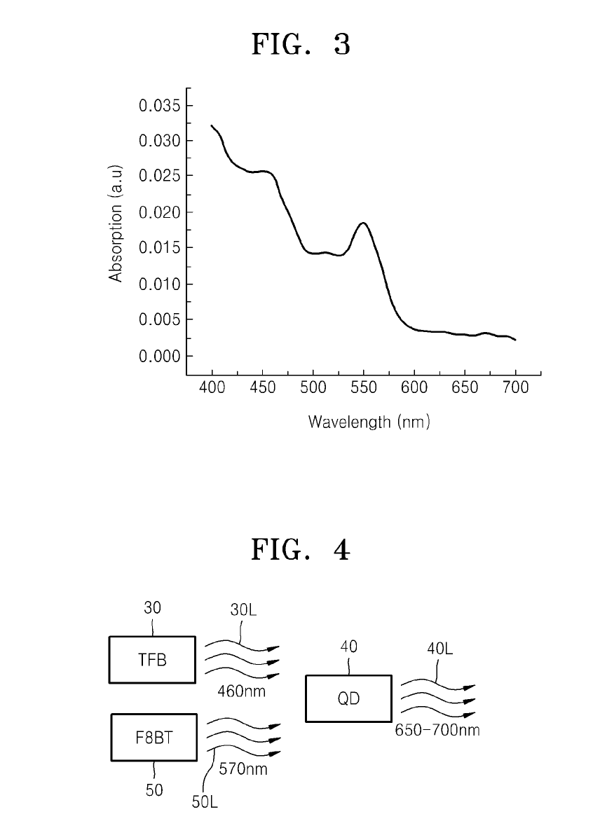

FIG. 3 illustrates an absorptivity spectrum with respect to a QD layer of a QD-LED device according to an exemplary embodiment.

Referring to FIG. 3, an absorbing area of the QD layer is evenly distributed through the visible region.

The luminescent center of the electron transport layer is green as shown in FIG. 1, and the luminescent center of the hole transport layer is blue as shown in FIG. 2, thus green light and blue light respectively emitted from the electron transport layer and the hole transport layer may be absorbed by the QD layer as the electron transport layer and the hole transport layer are each disposed on both sides of the QD layer. In this regard, a quantum efficiency of the QD layer may be improved, and as a result, a luminescence efficiency of the QD-LED device may be improved.

FIG. 4 schematically illustrates the processes above. That is, blue light 30L emitted from a hole transport layer 30 and green light 50L emitted from an electron transport layer 50 may be delivered to the QD layer 40. The green and blue light 50L and 30L delivered to the QD layer 40 may be used as energy that excites the QD layer 40, and accordingly, light 40L of an another region of wavelengths may be emitted from the QD layer 40.

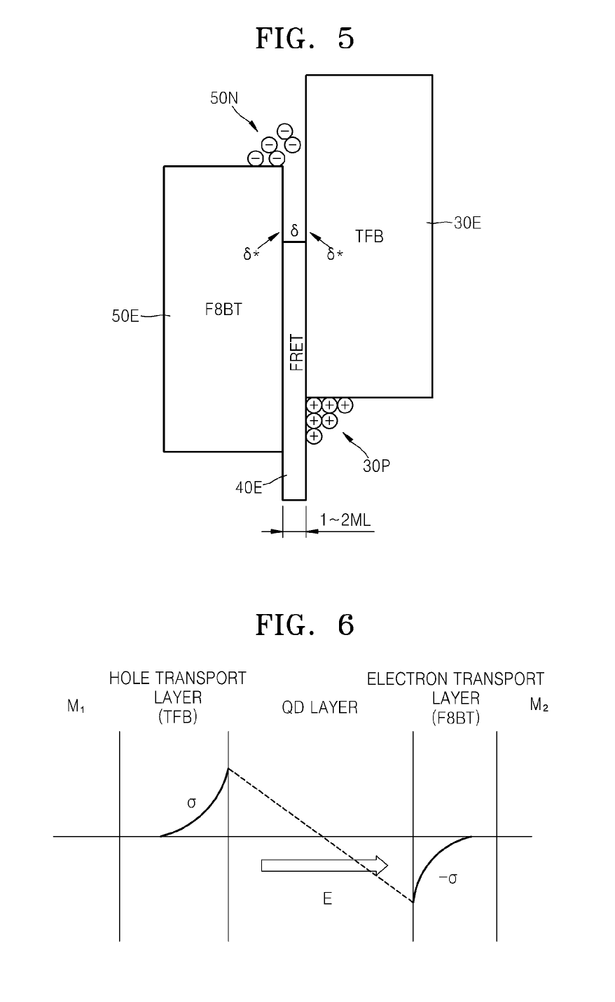

FIG. 5 illustrates charge accumulation according to an energy level difference between an electron transport layer and a hole transport layer in a QD-LED device according to an embodiment of the present invention.

In FIG. 5, a reference number 50E represents an energy level of the electron transport layer 50. A reference number 30E represents an energy level of the hole transport layer 30. A reference number 40E represents an energy level of the QD layer 40. Thus, the reference number 50E may symbolically represent an electron transport layer, and the reference numbers 30E and 40E may each represent a hole transport layer and a QD layer.

As shown in FIG. 5, the energy level 50E of the electron transport layer 50 is lower than the energy level 30E of the hole transport layer 30. When power is supplied to the electron transport layer 50 and the hole transport layer 30 according to the energy level difference, charges (electrons/holes) may be accumulated at an interface between the electron transport layer 50 and the hole transport layer 30.

Referring to FIG. 5, electrons 50N are accumulated on the electron transport layer 50, and holes 30P are accumulated on the hole transport layer 30.

Such accumulation of charges may increase a coupling efficiency of the electrons 50N and the holes 30P, thus a luminescence efficiency of the light emitting device may be increased.

In addition, as shown in FIG. 5, because there is the QD layer 40 between the electron transport layer 50 and the hole transport layer 30, a quantum efficiency according to the charges 50N and 30P accumulated at an interface of the electron transport layer 50 and the hole transport layer 30 may be increased. Also, a quantum efficiency of the QD layer 40 may be increased as the light emitted from the electron transport layer 50 and the hole transport layer 30 is delivered to the QD layer 40. In other words, a quantum efficiency of the QD layer 40 may be increased due to the charges 50N and 30P accumulated at the interface of the electron transport layer 50 and the hole transport layer 30, and due to forster resonant energy transfer (FRET) between an interface between the electron transport layer 50 and the QD layer 40 and an interface between the hole transport layer 30 and the QD layer 40.

FIG. 6 illustrates an electrical field E formed inside the device due to an increase in charge density as the charges accumulate in the QD-LED device according to an exemplary embodiment.

Due to the electrical field E, a drift velocity (v) of the charges increases, and thus electron mobility increases. Due to the increase in electron mobility, an intensity of turn-on voltage is relatively reduced.

Therefore, in a QD-LED device according to an exemplary embodiment, although an overall thickness of the device increases due to an increase in a thickness of an electron transport layer and/or a hole transport layer, a turn-on voltage of the device may be relatively reduced. This may be confirmed by the results of experiments that will be described later (FIG. 9).

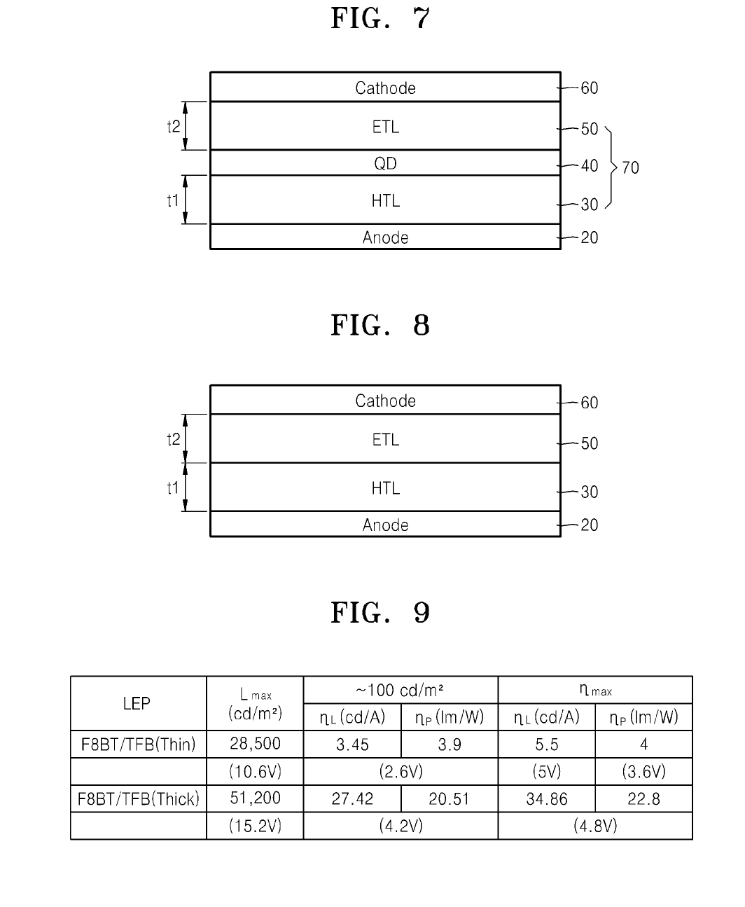

FIG. 7 illustrates a QD-LED device as an example of the LED device according to an exemplary embodiment.

Referring to FIG. 7, the hole transport layer 30 is on an anode 20. The anode 20 may be, for example, a transparent electrode such as indium tin oxide (ITO). The QD layer 40 is on the hole transport layer 30. The electron transport layer 50 is on the QD layer 40. The QD layer 40 may be, for example, a CdSe layer. A cathode 60 is on the electron transport layer 50. The cathode 60 may be, for example, a Ca/Al electrode. The electron transport layer 30 may be a material layer having a high hole mobility and luminescent properties which may be, for example, a poly(9,9-dioctylfluorene-co-N-(4-butylphenyl)diphenylamine (TFB) layer. Also, the hole transport layer 30 may be a QD layer or a monomolecular layer. The electron transport layer 50 is a material layer having a high hole mobility and luminescent properties which may be, for example, a poly(9,9-dioctylfluorene-co-benzothiadiazole (F8BT) layer. Moreover, the electron transport layer 50 may be a QD layer or a monomolecular layer.

The hole transport layer 30 has a first thickness t1. The first thickness t1 may be greater than a thickness of a conventional hole transport layer. For example, if a previously known thickness of a hole transport layer is 20 nm, the first thickness of the hole transport layer 30 may be greater than 20 nm. A range of the thickness of the hole transport layer 30 may be, for example, from about 60 nm to about 300 nm. Here, a second thickness t2 of the electron transport layer 50 may be equal to or greater than a thickness of a conventional electron transport layer.

Meanwhile, the second thickness t2 of the electron transport layer 50 may be greater than a thickness of a conventional electron transport layer. For example, if a previously known thickness of an electron transport layer is 40 nm, the second thickness of the electron transport layer 50 may be greater than 40 nm. A range of the thickness of the electron transport layer 30 may be, for example, from about 60 nm to about 300 nm. Here, the first thickness t1 of the hole transport layer 30 may be equal to or greater than a thickness of a conventional hole transport layer.

A thickness of the QD layer 40 may be in a range of, for example, about 20 nm to about 40 nm.

When the first thickness t1 of the hole transport layer 30 and the second thickness t2 of the electron transport layer 50 are in the corresponding ranges above, the hole transport layer 30, the QD layer 40, and the electron transport layer 50 may form a micro optical cavity 70. When the cavity 70 is used, a particular wavelengths may be selectively emitted from the QD layer 40 due to the resonance characteristics of the cavity 70, and thus an intensity of the light of the particular wavelengths may be increased. Also, by including the cavity 70, the QD-LED device according to an exemplary embodiment may become a QD-laser. In this case, the QD layer 40 is formed of a monolayer and may be designed in a photonic crystal structure.

The device illustrated in FIG. 7 may be manufactured by sequentially forming the anode 20, the hole transport layer 30, the QD layer 40, the electron transport layer 50, and the cathode 60 on a substrate (not shown). If necessary, a patterning process may be included. Each layer may be formed using a conventionally known method. Here, the electron transport layer 50 and the hole transport layer 30 may be formed with the thicknesses within the ranges stated above.

Meanwhile, as shown in FIG. 8, an LED device may include the electron transport layer 50 and the hole transport layer 30 without the QD layer 40. The device of FIG. 8 may be an OLED. The ranges of the thickness of the electron transport layer 50 and the hole transport layer 30 may be same with the corresponding thicknesses of FIG. 7.

The device of FIG. 8 may be manufactured by sequentially forming the anode 20, the hole transport layer 30, the electron transport layer 50, and the cathode 60 on a substrate (not shown).

FIG. 9 is a table summarizing the results of experiments showing an increase in luminescence efficiency and a relative decrease in driving voltage according to increases in thicknesses of the electron transport layer and the hole transport layer in the light emitting device of FIGS. 7 and 8. In the experiments, a thickness of the electron transport layer 50 is increased from 80 nm to 125 nm, and a thickness of the hole transport layer 30 is increased from 40 nm to 140 nm.

Referring to FIG. 9, FIG. 9 shows charge accumulation according to the thickness increase of the hole transport layer 30 and the electron transport layer 50 and that quantum dot efficiency due to the charge accumulation is increased.

Particularly, a luminescence efficiency of the light emitting device is increased from 5.5 cd/A to 35 cd/A as the thicknesses of the hole transport layer (or TFB) 30 and the electron transport layer (or F8BT) 50 are increased. Also, the luminescence efficiency is rapidly increased from 4 lm/W to 23 lm/W. Such results are caused by an increase in luminance of the device from 28,500 cd/m2 to 51,200 cd/m2 regardless of the decrease of current density due to the increase in the thicknesses of the hole transport layer 30 and the electron transport layer 50.

In FIG. 9, the voltages in the parentheses indicate voltages applied to obtain the results of the corresponding items. When the thicknesses of the hole transport layer 30 and the electron transport layer 50 are increased, each voltage value increases but is much less value than an increased value of the predicted voltage in consideration of the increased thicknesses of the hole transport layer 30 and the electron transport layer 50. For example, a driving voltage is predicted to be increased from 2.6 V to 8 V as the thicknesses increased as above, but the actual measured value was about 4.2 V. The results may be interpreted as it is caused by the electrical field E formed inside the device according to charge accumulation.

Thus, it has been confirmed through the results from the experiments that a driving voltage with respect to an increase of the thickness may be relatively reduced while charge accumulation may be increased and accordingly a luminescence efficiency may be increased by increasing thicknesses of the hole transport layer 30 and the electron transport layer 50.

Next, an experiment to prove that quantum dots generated in each layer are delivered to the QD layer 40 as the thicknesses of the electron transport layer 50 and the hole transport layer 30 are increased will be explained hereinafter.

In the current experiment, the QD layer 40 was interposed between the interfaces of the electron transport layer 50 and the hole transport layer 30. Here, a thickness of the hole transport layer 50 was fixed to be 75 nm, and a thickness of the QD layer 40 was fixed to be 20 nm.

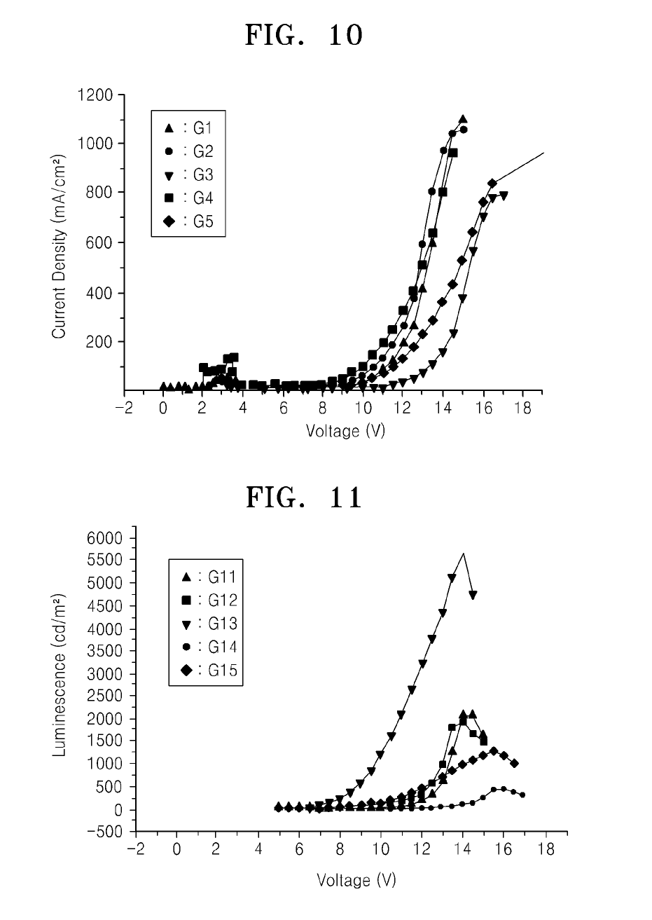

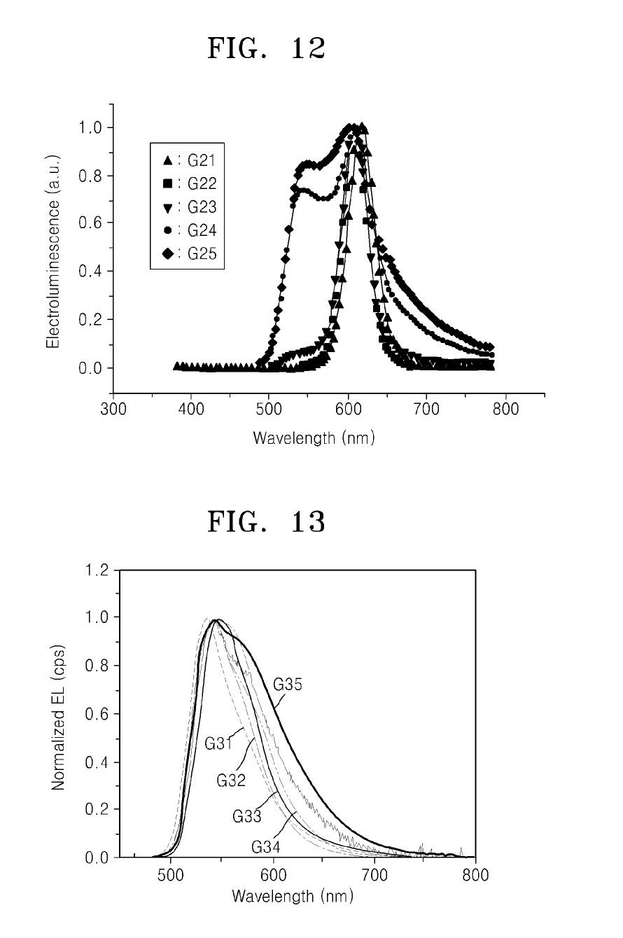

As the results of the current experiment, FIG. 10 illustrates a change in the current density according to the change in thickness of the hole transport layer 30. FIG. 11 illustrates a change in luminance, and FIG. 12 illustrates a change in a luminescence spectrum.

In FIG. 10, a horizontal axis shows voltages, and a vertical axis shows current densities. In FIG. 10, a first graph G1 represents the results of the hole transport layer 30 with a thickness of 25 nm, and a second graph G2 represents the results of the hole transport layer 30 with a thickness of 50 nm. Also, third to fifth graphs G3 to G5 each represents the hole transport layer 30 with a thickness of 75 nm, 100 nm, and 140 nm, respectively.

Referring to FIG. 10, as a thickness of the hole transport layer 30 increases, a current density is reduced.

In FIG. 11, a horizontal axis shows voltages, and a vertical axis shows luminance.

In FIG. 11, a first graph G11 represents change in luminances when the hole transport layer 30 has a thickness of 25 nm. Also, second to fifth graphs G12 to G15 each represents change in luminances when the hole transport layer 30 has a thickness of 50 nm, 75 nm, 100 nm, and 140 nm, respectively.

Referring to FIG. 11, as a thickness of the hole transport layer 30 is increased to 75 nm, an overall luminance first increased and then reduced later. Such result is interpreted as it is caused by reduction of quantum dot generation due to charges/holes density imbalance.

In FIG. 12, a first graph G21 represents luminescence spectrum change when the hole transport layer 30 has a thickness of 25 nm. Also, second to fifth graphs G22 to G25 represent the results of luminescence spectrum change when the hole transport layer 30 has thicknesses of 50 nm, 75 nm, 100 nm, and 140 nm, respectively.

Referring to FIG. 12, as a thickness of the hole transport layer 30 is increased to 75 nm, a luminescence spectrum with a center of the QD layer 40 may appear, but when the thickness of the hole transport layer 30 exceeds 75 nm, green light, center light of the electron transport layer 50, was observed.

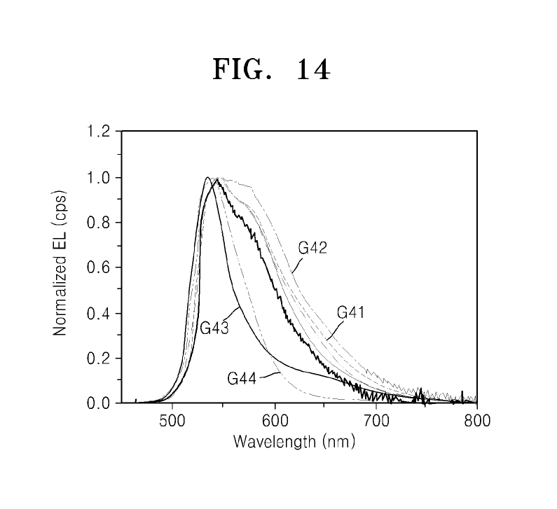

Next, the results of luminescent intensity amplification experiments as the hole transport layer 30, the electron transport layer 50, and the QD layer 40 form the micro optical cavity 70 will now be explained. FIGS. 13 and 14 illustrate the results of the experiments.

FIG. 13 illustrates an electroluminescence (EL) spectrum change according to formation of the micro optical cavity when only a thickness of the electron transport layer 50 was changed.

In FIG. 13, a first graph G31 represents the results of the electron transport layer 50 with a thickness of 25 nm. Also, second to fourth graphs G32 to G34 represent the electron transport layer 50 with thicknesses of 55 nm, 215 nm, and 245 nm, respectively.

Referring to FIG. 13, as a thickness of the electron transport layer 50 increases, an intensity of a range of wavelengths for yellow is increased.

FIG. 14 illustrates an electroluminescence (EL) spectrum change according to formation of the micro optical cavity when only a thickness of the hole transport layer 30 is changed.

In FIG. 14, a first graph represents the results of the hole transport layer 30 with a thickness of 25 nm. Also, second to fourth graphs G42 to G44 represent the hole transport layer 30 with thicknesses of 75 nm, 110 nm, and 135 nm, respectively.

Referring to FIG. 14, as a thickness of the hole transport layer 30 increases, an intensity of a range of wavelengths for blue is increased.

As described above, according to the one or more of the above-described exemplary embodiments, it may be known that a quantum efficiency of a device may be additionally increased as an intensity of a specific wavelength may be increased with an formation of a micro optical cavity 70 by increasing thicknesses of a hole transport layer 30 and an electron transport layer 50 of an OLED device.

It should be understood that the exemplary embodiments described herein should be considered in a descriptive sense only and not for purposes of limitation. Descriptions of features or aspects within each embodiment should typically be considered as available for other similar features or aspects in other embodiments.

What is claimed is:

1. A light emitting device comprising:
a substrate;
a first electrode disposed on the substrate;
a hole transport layer disposed on the first electrode;
an electron transport layer disposed on the hole transport layer; and
a second electrode disposed on the electron transport layer,
wherein the hole transport layer has a thickness of greater than 20 nm or the electron transport layer has a thickness of greater than 40 nm.

2. The light emitting device of claim 1, wherein a quantum dot (QD) layer is interposed between the hole transport layer and the electron transport layer.

3. The light emitting device of claim 2, wherein the hole transport layer, the electron transport layer, and the QD layer, together, form a micro optical cavity.

4. The light emitting device of claim 1, wherein the thickness of the hole transport layer is in a range of about 60 nm to about 300 nm.

5. The light emitting device of claim 1, wherein the thickness of the electron transport layer is in a range of about 60 nm to about 300 nm.

6. The light emitting device of claim 1, wherein each of the hole transport layer and the electron transport layer is a QD layer, a monomolecular layer, or a polymer layer.

7. The light emitting device of claim 2, wherein the thickness of the hole transport layer is in a range of about 60 nm to about 300 nm.

8. The light emitting device of claim 2, wherein the thickness of the electron transport layer is in a range of about 60 nm to about 300 nm.

9. The light emitting device of claim 2, wherein each of the hole transport layer and the electron transport layer is a QD layer, a monomolecular layer, or a polymer layer.

10. A method of manufacturing a light emitting device, the method comprising:
forming a first electrode formed on a substrate,
forming a hole transport layer on the first electrode,
forming an electrode transport layer on the hole transport layer, and
forming a second electrode on the electrode transport layer,
wherein the hole transport layer has a thickness of greater than 20 nm or the electron transport layer has a thickness of greater than 40 nm.

11. The method of claim 10, further comprising forming a QD layer between the hole transport layer and the electrode transport layer.

12. The method of claim 11, wherein the hole transport layer, the electron transport layer, and the QD layer, together, form a micro optical cavity.

13. The method of claim 10, wherein the thickness of the hole transport layer is in a range of about 60 nm to about 300 nm.

14. The method of claim 10, wherein thickness of the electron transport layer is in a range of about 60 nm to about 300 nm.

15. The method of claim 11, wherein the thickness of the hole transport layer is in a range of about 60 nm to about 300 nm.

16. The method of claim 11, wherein the thickness of the electron transport layer is in a range of about 60 nm to about 300 nm.

17. The light emitting device of claim 2, wherein a thickness of the QD layer is in a range of about 20 nm to about 40 nm.

18. The light emitting device of claim 1, wherein the thickness of the hole transport layer is about 140 nm, and a thickness of the electron transport layer is about 125 nm.

19. The light emitting device of claim 2, wherein the thickness of the hole transport layer is 75 nm, and the thickness of the electron transport layer is 20 nm.
